(19) United States
(12) Patent Application Publication
(10) Pub. No.: US 2011/0188177 A1
(43) Pub. Date: Aug. 4, 2011

(54) Dome Assemblies for Providing Tactile Feedback on Display Windows and Related Portable Electronic Devices and Methods

(76) Inventors: Mats Klevermand, Helsingborg (SE); Gunnar Klinghult, Lund (SE)

(21) Appl. No.: 12/698,294

(22) Filed: Feb. 2, 2010

(51) Int. Cl. H05K 5/00; H01H 13/70

(52) U.S. Cl. 361/679.01; 200/5 A

(57) ABSTRACT

Portable electronic devices are provided including a housing; a display connected to the housing; at least one actuator disposed in the housing and coupled to the display; and at least one mechanical dome associated with the at least one actuator, the at least one mechanical dome configured to implode and/or expand responsive to activation of a button on the display of the portable electronic device to provide a user with tactile feedback associated with the button. Related dome assemblies and methods are also provided.

### FIELD

The present invention relates generally to portable electronic devices and, more particular, to tactile feedback provided by the portable electronic devices.

### BACKGROUND

Many portable electronic devices, such as cellular terminals and pagers, include indicators to alert a user that something has happened or that some action is required. For example, an audible ringer can be used to indicate that a telephone call is being received or that a page has been received. Alternately, a vibrating assembly that causes a cellular terminal to vibrate can be used to provide silent indication. Such vibrating assemblies typically include a small electric motor, referred to as a vibrator motor, that drives a rotating shaft having an unbalanced or “eccentric” weight (i.e., a weight with a center of gravity that is radially displaced from the axis of rotation), thereby causing a vibration when the shaft rotates.

Users of these portable electronic devices typically desire fast and distinct tactile feedback when activating a “virtual” button on a touch enabled display window of the portable electronic device. Some conventional portable electronic devices provide tactile feedback solutions are using the vibrating assemblies discussed above. In these devices, the vibrator serves as both a “normal” vibrator for alerting the user and a vibrator for providing tactile feedback and is typically mounted in the mechanical structure of the portable electronic device. Because the vibrator is mounted to the mechanical structure of the portable electronic device, the vibration may be spread over the complete mechanical structure of the device, which is not ideal for localized tactile feedback.

### SUMMARY

Some embodiments provide portable electronic devices including a housing; a display connected to the housing; at least one actuator disposed in the housing and coupled to the display; and at least one mechanical dome associated with the at least one actuator, the at least one mechanical dome configured to implode and/or expand responsive to activation of a button on the display of the portable electronic device to provide a user with tactile feedback associated with the button.

In further embodiments, the portable electronic device may include a plurality of buttons and each of the plurality of buttons may have a corresponding actuator-dome pair.

In still further embodiments, the portable electronic device may include a plurality of buttons and the plurality of buttons may have a single corresponding actuator-dome pair.

In some embodiments, a window may be associated with the display and the at least one mechanical dome may be directly connected to the window and the associated at least one actuator is configured to control a state of the dome.

In further embodiments, a window may be associated with the display, the display may have an associated display assembly, the at least one mechanical dome may be connected to the display assembly and the associated at least one actuator may be configured to control a state of the dome.

In still further embodiments, a window may be associated with the display, the window may have a front portion and first and second side portions, the at least one mechanical dome may be connected to a side portion of the window the associated at least one actuator may be configured to control a state of the dome.

In some embodiments, the button may be a virtual and/or mechanical button and the actuator may be a memory alloy, electrical activated polymer or piezoelectric ceramic actuator.

Further embodiments of the present invention provide dome assemblies for use portable electronic devices, the dome assemblies include at least one actuator disposed in a housing of a portable electronic device and coupled to a display of the portable electronic device; and at least one mechanical dome associated with the at least one actuator. The at least one mechanical dome is configured to implode and/or expand responsive to activation of a button on the display of the portable electronic device to provide a user with tactile feedback associated with the button.

In still further embodiments, the portable electronic device may include a plurality of buttons and each of the plurality of buttons may have a corresponding actuator-dome pair.

In some embodiments, the portable electronic device may include a plurality of buttons and the plurality of buttons may have a single corresponding actuator-dome pair.

In further embodiments, a window may be associated with the display, the at least one mechanical dome may be directly connected to the window and the associated at least one actuator may be configured to control a state of the dome.

In still further embodiments, a window may be associated with the display, the display may have an associated display assembly, the at least one mechanical dome may be connected to the display assembly and the associated at least one actuator may be configured to control a state of the dome.

In some embodiments, a window may be associated with the display, the window has a front portion and first and second side portions, the at least one mechanical dome may be connected to a side portion of the window and the associated at least one actuator may be configured to control a state of the dome.

In further embodiments, the button may be a virtual and/or mechanical button and the actuator may be a memory alloy, electrical activated polymer or piezoelectric ceramic actuator.

Still further embodiments provide methods of operating a portable electronic device, the method includes activating a button on a display of the portable electronic device; and imploding and/or expanding at least one mechanical dome responsive to the activation of the button on the display to provide a user of the portable electronic device with tactile feedback associated with the button.

In some embodiments, the method may further include controlling a state of the at least one mechanical dome using at least one actuator associated with the at least one mechanical dome.

In further embodiments, the portable electronic device may include a plurality of buttons and each of the plurality of buttons may have a corresponding actuator-dome pair.

In still further embodiments, the portable electronic device may include plurality of buttons and the plurality of buttons may have a single corresponding actuator-dome pair.

In some embodiments, the button may be a virtual and/or mechanical button and the actuator may be a memory alloy, electrical activated polymer or piezoelectric ceramic actuator.

Other electronic devices and/or methods according to embodiments of the invention will be or become apparent to one with skill in the art upon review of the following drawings and detailed description. It is intended that all such additional electronic devices and methods be included within this description, be within the scope of the present invention, and be protected by the accompanying claims.

### BRIEF DESCRIPTION

The accompanying drawings, which are included to provide a further understanding of the invention and are incorporated in and constitute a part of this application, illustrate certain embodiments of the invention.

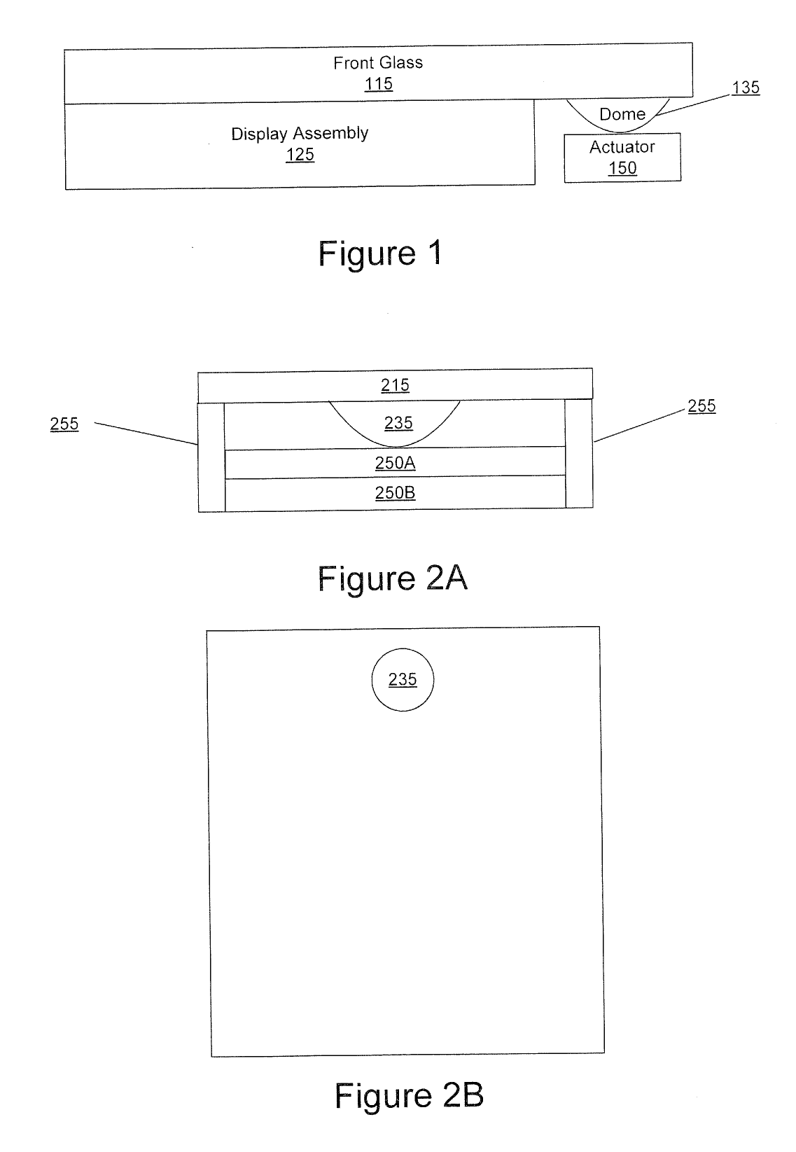

FIG. 1 is a cross section of portable electronic devices including a dome assemblies in accordance with some embodiments of the present invention.

FIGS. 2A and 2B are a top view and a plan view of portable electronic devices in accordance with some embodiments of the present invention.

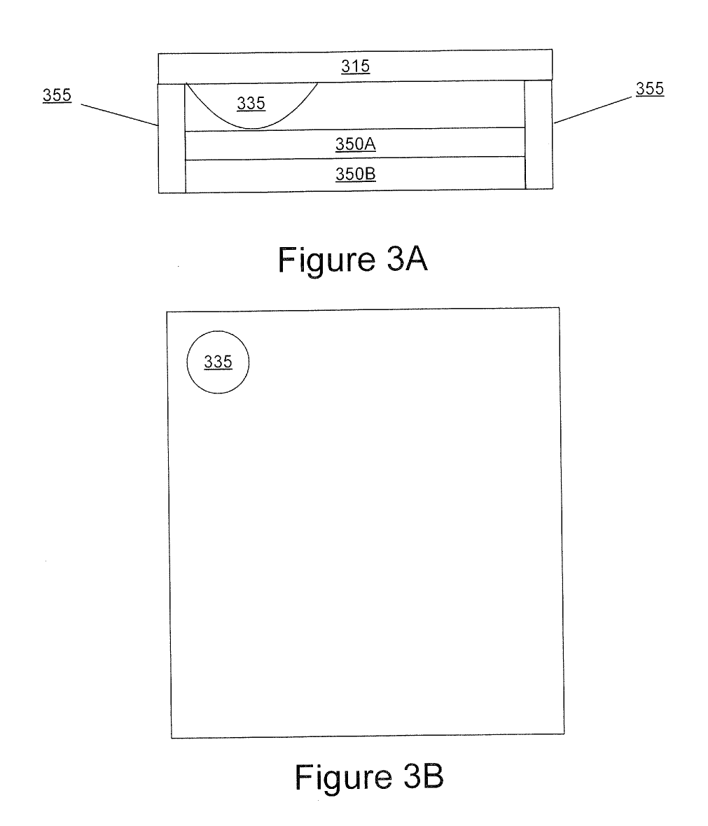

FIGS. 3A and 3B are a top view and a plan view of portable electronic devices in accordance with some embodiments of the present invention.

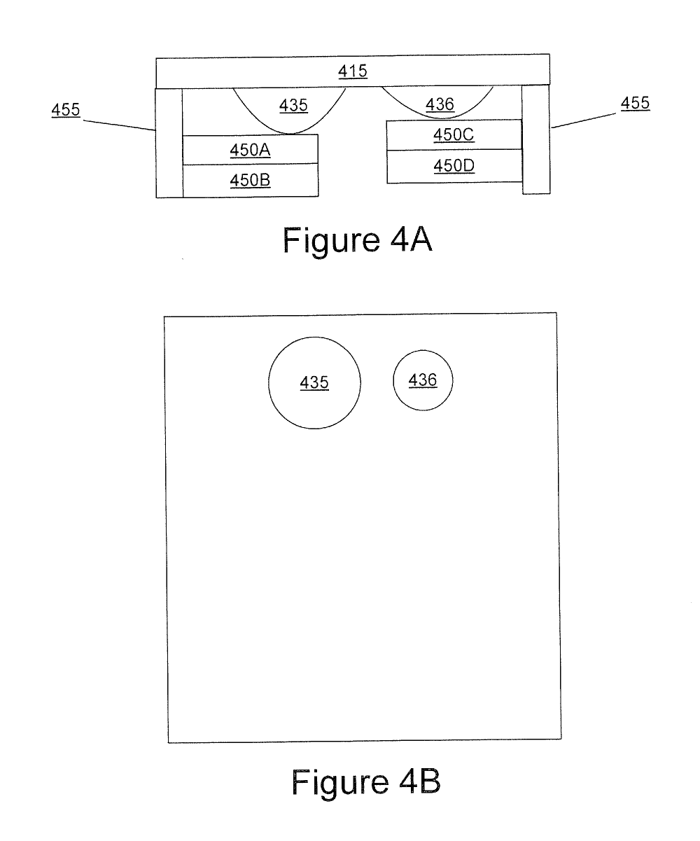

FIGS. 4A and 4B are a top view and a plan view of portable electronic devices in accordance with some embodiments of the present invention.

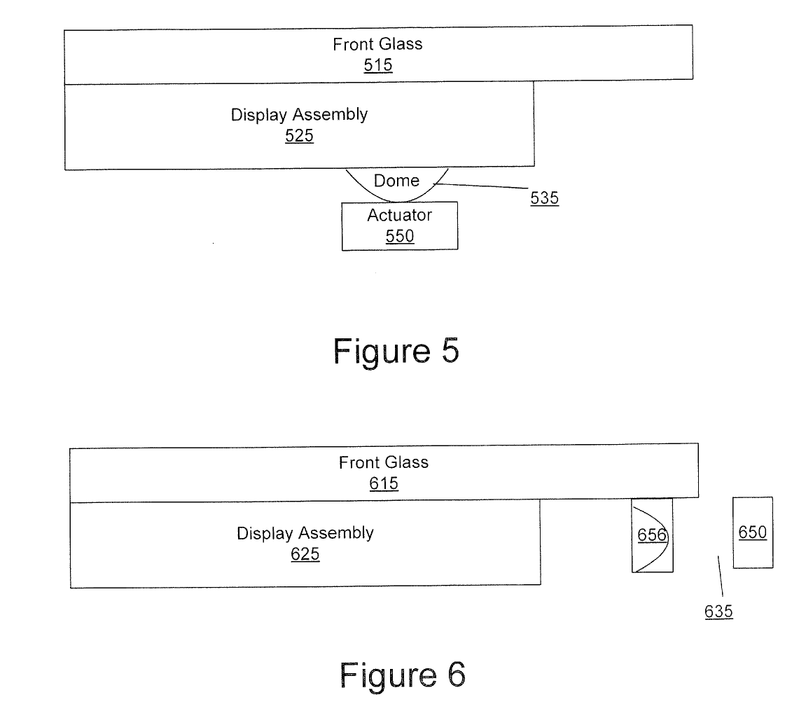

FIG. 5 is a cross section of portable electronic devices including dome assemblies in accordance with some embodiments of the present invention

FIG. 6 is a cross section of portable electronic devices including dome assemblies in accordance with some embodiments of the present invention

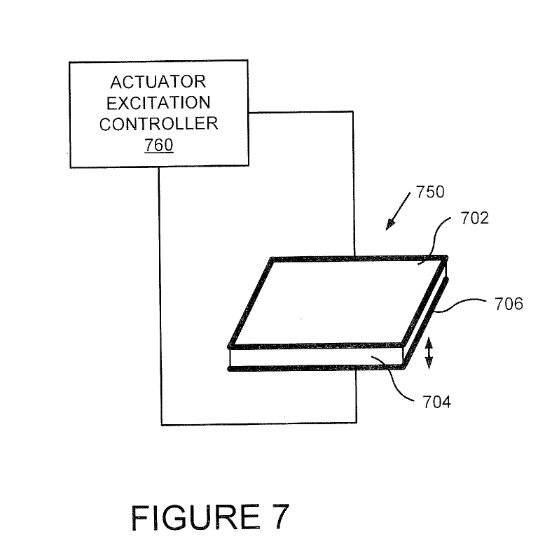

FIG. 7 is a schematic block diagram, and associated operational methods, for an excitation controller and an actuator that operate according to some embodiments of the present invention.

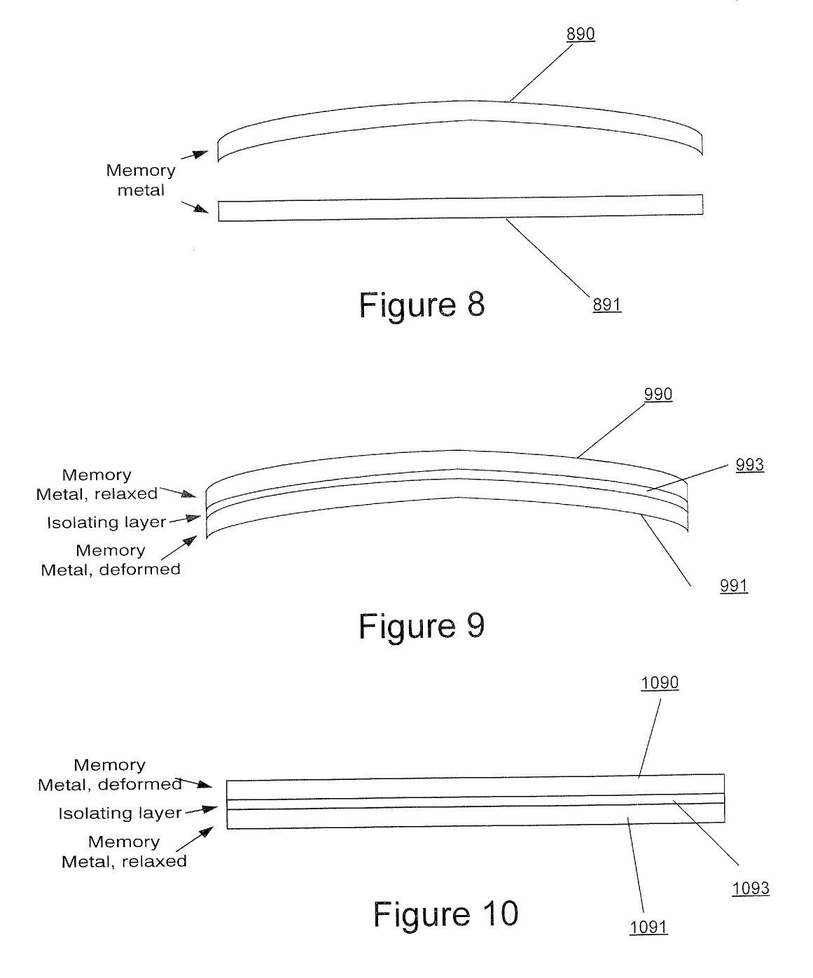

FIGS. 8 through 10 are diagrams of an actuator in accordance with various embodiments of the present invention.

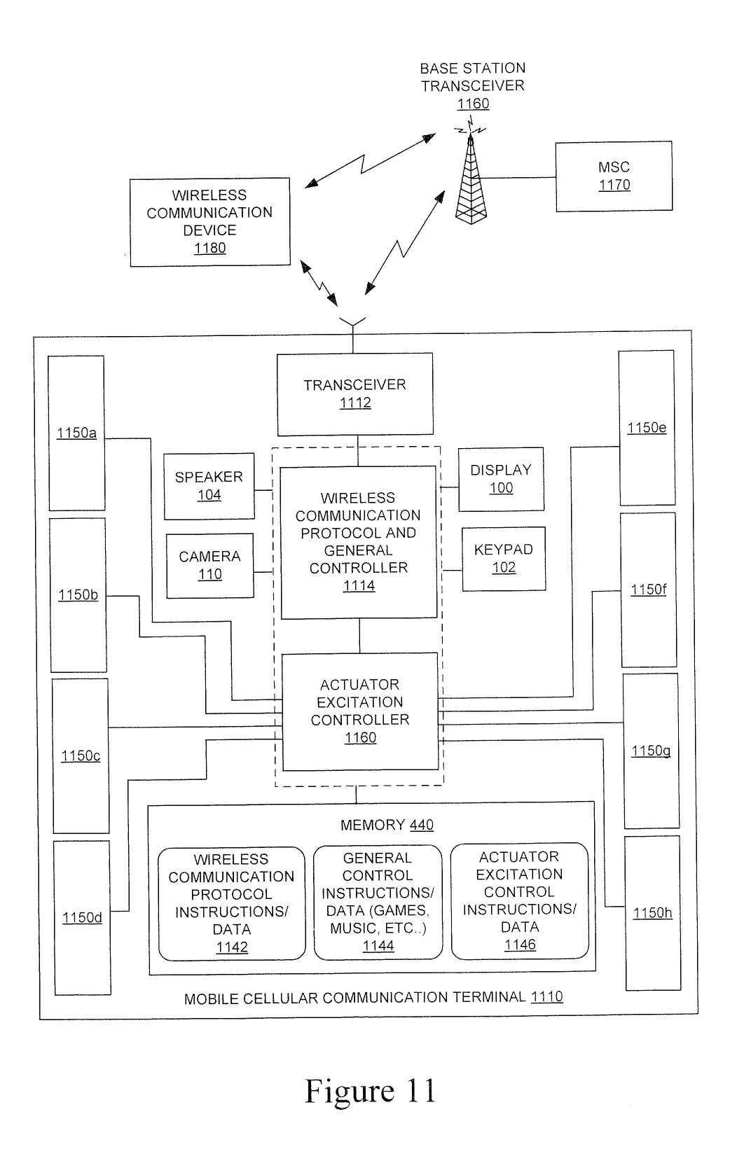

FIG. 11 is a schematic block diagram, and associated operational methods, for a portable electronic device and a cellular communication system that operate according to some embodiments of the present invention.

### DETAILED DESCRIPTION OF EMBODIMENTS OF THE INVENTION

The present invention will be described more fully hereinafter with reference to the accompanying figures, in which embodiments of the invention are shown. This invention may, however, be embodied in many alternate forms and should not be construed as limited to the embodiments set forth herein.

Accordingly, while the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention as defined by the claims. Like numbers refer to like elements throughout the description of the figures.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises”, “comprising,” “includes” and/or “including” when used in this specification, specify the presence of stated features, integers, steps, operations, elements, and/or components, but do not preclude the presence or addition of one or more other features, integers, steps, operations, elements, components, and/or groups thereof. Moreover, when an element is referred to as being “responsive” or “connected” to another element, it can be directly responsive or connected to the other element, or intervening elements may be present. In contrast, when an element is referred to as being “directly responsive” or “directly connected” to another element, there are no intervening elements present. As used herein the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element without departing from the teachings of the disclosure. Although some of the diagrams include arrows on communication paths to show a primary direction of communication, it is to be understood that communication may occur in the opposite direction to the depicted arrows.

Some embodiments are described with regard to block diagrams and operational flowcharts in which each block represents a circuit element, module, or portion of code which comprises one or more executable instructions for implementing the specified logical function(s). It should also be noted that in other implementations, the function(s) noted in the blocks may occur out of the order noted. For example, two blocks shown in succession may, in fact, be executed substantially concurrently or the blocks may sometimes be executed in the reverse order, depending on the functionality involved.

As discussed above, users of portable electronic devices typically desire fast and distinct tactile feedback when activating a “virtual” button on a touch enabled display window of the portable electronic device. The response/vibration should mainly be localized on the window so that the feedback is directed to the activating finger and not to other parts of the device, for example, the backside. Conventional devices using a vibrator to provide this tactile feedback may fail to provide the localized feedback desired by the user. Accordingly, some embodiments discussed herein provide tactile feedback localized on a display touch window of the portable electronic device utilizing an actuator controlled mechanical dome as will be discussed further below with respect to FIGS. 1 through 11.

According to some embodiments discussed herein, feedback (click/vibrations) emanate from the window of the portable electronic device, i.e. the physical part of the device that is touched/pressed by a finger of the user. It will be understood, the click/vibration sensation will, however, inevitably leak into the surrounding mechanical structure of the portable electronic device, but this will be significantly lower than the high amplitude that is expected on the window when the system is designed properly. Furthermore, contrary to conventional devices where the vibrator is used for both the tactile feedback and general vibrations, the systems according to embodiments discussed herein can be designed independently. In conventional devices, when a single vibrator is used for both use-cases, it may be difficult to achieve optimum behavior for both cases. Thus, having an independent system for tactile feedback using a dome assembly in accordance with some embodiments of the present invention, the vibrator function can be optimized for vibrations used for, for example, incoming calls when the phone is in silent mode.

For purposes of illustration and explanation only, various embodiments of the present invention are described herein in the context of portable electronic devices. It will be understood, however, that the present invention is not limited to such embodiments and may be embodied generally in any electronic device that includes at least one mechanical dome assembly. For example, embodiments of the present invention may be embodied in user interfaces for electronic games and/or music players. The mechanical dome may be provided by, for example, a preformed metal plate, plastic or any material that can provide a tactile feedback in accordance with embodiments discussed herein.

Referring to FIG. 1, a cross section of a portable electronic device including a dome assembly in accordance with some embodiments will be discussed. As illustrated in FIG. 1, the portable electronic device includes front glass/window 115, a display assembly 125, at least one mechanical dome 135 attached to the front glass 115 and at least one actuator 150 associated with the at least one mechanical dome 135. As used herein, “dome assembly” refers to the combination of the at least one mechanical dome 135 and the corresponding at least one actuator 150. Although FIG. 1 only includes a single dome assembly, i.e., a mechanical dome-actuator pair, embodiments of the present invention are not limited to this configuration. For example, multiple dome assemblies may be provided, such as a dome assembly for each button on the portable electronic device.

Furthermore, it will be understood that although not illustrated in FIG. 1, the portable electronic device may include a user interface, for example, a keypad, a speaker, a microphone, a camera and housing as well as other circuits/modules known to those of skill in the art to be included in portable electronic devices.

Referring again to FIG. 1, the mechanical dome 135 associated with the at least one actuator 150 is configured to implode and/or expand responsive to activation of a button on the display of the portable electronic device to provide a user with tactile feedback associated with the button. In other words, responsive to selection of a button by a user of the portable electronic device, the actuator 150 associated with the mechanical dome 135 causes the mechanical dome 135 to implode/expand to provide the user of the portable electronic device tactile feedback responsive to selecting the button.

As used herein, a “button” refers to a mechanical button or a virtual button. Furthermore, the portable electronic device may have a combination of both mechanical and virtual buttons without departing from the scope of embodiments discussed herein. As used herein, a “virtual button” refers to a simulated button. For example, a virtual button may be depicted on a touch screen of a portable electronic device. In accordance with some embodiments discussed herein, when the virtual button on the touch screen is selected by a user of the portable electronic device, the actuator-dome pair associated with the virtual button may provide the user with tactile feedback for the button as discussed herein. Furthermore, in embodiments where the button is a mechanical button, the actuator-dome pair may provide increased tactile feedback associated with the mechanical button as discussed herein.

As discussed above, one or more buttons may be included on the portable electronic device. In some embodiments, each of the plurality of buttons has a corresponding actuator-dome pair. In other embodiments, the plurality of buttons may share a single actuator-dome pair.

As illustrated in FIG. 1, in some embodiments, the at least one mechanical dome 135 is directly connected to the window 115 and the actuator is configured to control a state of the dome, i.e. implosion and expansion of the dome. As illustrated in FIGS. 2A and 2B, the dome 235 may be provided between the front glass 215 and the actuator 250A/250B in the middle of the device between side portions 255 thereof. Alternatively, as illustrated in FIGS. 3A and 3B, the dome 335 may be provided between the front glass 315 and the actuator 350A/350B closer to one of the side portions 355 thereof.

Referring now to FIGS. 4A and 4B, in some embodiments more than one dome assembly or dome-actuator pair 450 may be provided in the portable electronic device. As illustrated in FIGS. 4A and 4B, a first mechanical dome 435 is provided between the front glass 415 and the actuator 450A/450B and a second dome 436 is provided between the front glass 450C/450D. As illustrated in FIGS. 4A and 4B, the domes 435 and the actuators 450A, B, C and D may be different sizes without departing from the scope of the present application.

As illustrated in FIG. 5, in some embodiments, the dome 535 and the associated actuator 550 may be provided on the display assembly 525, opposite the front glass 515. These portable electronic devices may be thicker than the devices discussed above with respect to FIGS. 1 through 4B.

As illustrated in FIG. 6, in some embodiments, the dome 635 and the actuator 650 may be provided on a side portion 656 of the device. These embodiments may also require a larger housing than those discussed above with respect to FIGS. 1 through 4B.

As will be appreciated, although various embodiments of the portable electronic device are illustrated in FIGS. 1 through 6 as having one or two dome assemblies, embodiments of the present invention is not limited thereto. Instead, any number of dome assemblies may be at least partially disposed in one or more surfaces of an electronic device and controlled in accordance with various embodiments of the present invention.

The at least one actuator 150, 250, 350, 450, 550 and 650 may be provided by, for example, a memory alloy, an electrical activated polymer (EAP) or a piezoelectric ceramic. An EAP is a polymer material that can change size and shape in response to electrical stimulus.

EAP can be used as an actuator for a flat panel speaker/vibrator. This actuator could either work as an actuator for the haptic feedback at low frequency or as a low frequency improver together with a high frequency actuator as a loudspeaker and also of course both functions at the same time. The EAP material can be used in either a bimorph bending bar or as a membrane. In both cases they will be mechanically attached in one point on the panel. One or several of these bimorph actuators can then be used. Each actuator can then be optimized for a specific frequency. This can give higher efficiency when several frequencies are used.

One type of EAP material suitable as actuator for this application is called Ionic Polymer Metallic Composite, IPMC. According to the literature it has the following properties: Low drive voltage, 1-5 V; Response up to several hundred of Hertz; and Soft material and durability of many bending cycles. The material can produce much bigger strain than piezoelectric ceramics.

Another of EAP material is the dielectric type EAP manufactured by, for example, AMI and Danfoss. This material exists today in production used as membrane type actuators. The drawback with this material is the need for very high drive voltage, for example, around 1 kV. Other types of EAP materials exist that can be used, for example, VHB 4910 made by 3M Corporation.

By using this material as an actuator for a flat panel speaker in a portable electronic device, the material/phone could withstand mechanical shocks much better than conventional devices. Furthermore, better output response may be obtained on lower frequencies as EAP has a much bigger strain than a piezoelectric actuator thereby mowing more air. Piezoelectric material has a typical 0.1% strain, EAP material can rang from 1.0% to above 100% of strain.

Thus, according to some embodiments, EAP material may be used in the actuator configured to change the states of a mechanical dome in accordance with some embodiments of the present invention. As illustrated in FIG. 7, the actuator 750 may be controlled by an actuator excitation controller 760 in the portable electronic device as illustrated in FIG. 11 set out below. An actuator excitation controller 760 is configured to control the actuator so that the actuator can control the states of the dome to provide tactile feedback to the user of the portable electronic device. As discussed above, in some embodiments, the actuator may be an EAP. In these embodiments, the EAP transducer 750 may include a first electrode 702 and a second electrode 704, and an EAP material 706 coupled therebetween. The excitation controller 760 may be configured to control an electric field across the first and second electrodes 702 and 704 to regulate attractive forces therebetween and, resultantly, deformation of the EAP material 706, such as variation in thickness of the EAP material 706. To cause a larger variation in thickness in response to stimulation, the EAP 750 may be formed by stacking a plurality of layers of the first electrode 702, EAP material 706, and second electrode 704. The excitation controller 760 regulates the rate at which the voltage across the electrodes 702 and 704 increases and decreases, for example, the rate at which the voltage rises from zero volts to full voltage and/or from fold voltage to zero volts) so as to control the rate of contraction/expansion of the EAP material 706. Thus, for example, the excitation controller 760 can control the EAP transducer 750 to rapidly contract the EAP material 706 to provide what a user may feel is a slap of the user's hand, or to slowly contract the EAP material 406 to provide what may feel like a slow shift/movement of the electronic device housing in the user's hand.

Referring now to FIGS. 8 through 10, the actuator may also be provided by a memory alloy actuator. The memory metal layers 890, 891 can be rectangular, square or round. In some embodiments illustrated in FIG. 8, one layer 890 can be performed curved. The performing of the memory metal is done at manufacturing. The other layer 891 is preformed flat.

As illustrated in FIG. 9, the two memory metal layers 990 and 991 may be mounted together and must be electrically isolated from one another by, for example, and isolating layer 993. The isolating layer 993 may include, for example, kapton or Teflon. During the mounting, the flat layer 991 is deformed to the curved shape 990.

As illustrated in FIG. 10, when the lower (flat) layer 1091 is heated the metal will contract and return to its original relaxed shape. When this happens, the curved layer 1090 is deformed and the shape of the curved layer 1090 is now flat.

When the upper (curved) layer 890, 990 and 1090 is heated it will return to its curved original relaxed shape. Thus, the structure has two bistable states and is capable of being used an actuator in accordance with some embodiments of the present invention.

The memory metal may be heated by letting a current flow through one of the layers. Only a short pulse of current, less than about 0.5 s, is needed as the reaction of memory metal is fast. The memory metal actuator can be driven by two digital output ports and if a higher current is needed an additional transistor on each port can be used. This drive principle is totally silent, instant and bistable, which means that it only consumes power at the short time when it moves. Memory metal is also inexpensive, requires very few details and has a very high density.

Referring now to FIG. 11, a schematic block diagram illustrating a portable electronic device 1110 and a cellular communication system in accordance with some embodiments of the present invention will be discussed. The portable electronic device 1110 may be similar to the portable electronic devices discussed above with respect to FIGS. 1 through 6, but the portable electronic device 1110 includes eight dome assemblies 1150a-h in accordance with some embodiments of the present invention. As discussed above, the number of dome assemblies can vary and is only limited by the size of the portable electronic device.

The portable electronic device 1110 may communicate with a cellular base station transceiver 1160 connected to a mobile switching center (“MSC”) 1170, and/or it may communicate through a short range network directly with another wireless communication device 1180. The portable electronic device 1110 can therefore include a transceiver 1112 and a wireless communication protocol controller (“communication controller”) 1114 that are configured to communicate through a wireless air interface with the base station transceiver 1160 and/or with the other wireless communication device 1180. The transceiver 1112 typically includes a transmitter circuit and a receiver circuit which cooperate to transmit and receive radio frequency signals. The communication controller 1114 can be configured to encode/decode and control communications according to one or more cellular protocols, which may include, but are not limited to, Global Standard for Mobile (GSM) communication, General Packet Radio Service (GPRS), enhanced data rates for GSM evolution (EDGE), code division multiple access (CDMA), wideband-CDMA, CDMA2000, and/or Universal Mobile Telecommunications System (UMTS). The communication controller 1114 may alternatively or additionally encode/decode and control communications according to one or more short range communication protocols, which may include, but are not limited to Bluetooth and/or WiFi such as IEEE 802.11 (e.g., IEEE 802.11b-g).

The portable electronic device 1110 can include a display 100, the user input interface 102 (e.g., virtual keypad), the speaker 104, and the camera 110.

With continuing reference to FIG. 11, the excitation controller 1160 can separately control each of the dome assemblies 1150a-h, and may, for example, simultaneously excite all of the actuators or less than all the actuators in the dome assemblies 1150a-h to expand/implode the corresponding domes to provide tactile feedback to a user of the portable electronic device. The actuator excitation controller 1160 may be configured to excite an actuator of a dome assembly responsive to activation of a button on the portable electronic device. Excitation of the actuators causes the corresponding dome to implode/expand providing tactile feedback to the user responsive to activation of the button.

The communication controller 1114 may generate an alert signal in response to receiving a phone call and/or a data message from the communication device 1180 and/or from another communication device via, for example, the base station transceiver 1160. When a user has not placed the portable electronic device 1110 in a mute mode, the communication controller 414 may generate a ring signal through the speaker 104. In contrast, when the portable electronic device 1110 has been placed in a mute mode, the portable electronic device may vibrate.

Although various functionality of the portable electronic device 1110 has been shown in FIG. 11 within separate blocks, it is to be understood that two or more of these functions may be combined in a single physical integrated circuit package and/or the functionality described for one or the blocks may be spread across two or more integrated circuit packages. For example, the functionally described herein for the communication controller 1114 and the excitation controller 1160 may be combined within shared instruction execution circuitry, such as within a general purpose processor and/or a digital signal processor, that executes instructions within a memory 1140. Accordingly, the memory 1140 can include wirelessly communication protocol instructions and data 1142, general control instructions and data 1144 (e.g., video games, music player, etc.), and actuator excitation control instructions and data 1146 that are executed by the instruction execution circuitry to carry out one or more of the embodiments described herein.

In the drawings and specification, there have been disclosed exemplary embodiments of the invention. However, many variations and modifications can be made to these embodiments without substantially departing from the principles of the present invention. Accordingly, although specific terms are used, they are used in a generic and descriptive sense only and not for purposes of limitation, the scope of the invention being defined by the following claims.

That which is claimed:

1. A portable electronic device comprising:
a housing;
a display connected to the housing;
at least one actuator disposed in the housing and coupled to the display; and
at least one mechanical dome associated with the at least one actuator, the at least one mechanical dome configured to implode and/or expand responsive to activation of a button on the display of the portable electronic device to provide a user with tactile feedback associated with the button.

2. The portable electronic device of claim 1, wherein the portable electronic device comprises a plurality of buttons and wherein each of the plurality of buttons has a corresponding actuator-dome pair.

3. The portable electronic device of claim 1, wherein the portable electronic device comprises a plurality of buttons and wherein the plurality of buttons have a single corresponding actuator-dome pair.

4. The portable electronic device of claim 1, further comprising a window associated with the display and wherein the at least one mechanical dome is directly connected to the window and wherein the associated at least one actuator is configured to control a state of the dome.

5. The portable electronic device of claim 1, further comprising a window associated with the display, wherein the display has an associated display assembly, wherein the at least one mechanical dome is connected to the display assembly and wherein the associated at least one actuator is configured to control a state of the dome.

6. The portable electronic device of claim 1, further comprising a window associated with the display, wherein the window has a front portion and first and second side portions, wherein the at least one mechanical dome is connected to a side portion of the window and wherein the associated at least one actuator is configured to control a state of the dome.

7. The portable electronic device of claim 1, wherein the button comprises a mechanical and/or virtual button and wherein the actuator comprises at least one of a memory alloy, electrical activated polymer and piezoelectric ceramic actuator.

8. A dome assembly for use in a portable electronic device, the dome assembly comprising:
at least one actuator disposed in a housing of a portable electronic device and coupled to a display of the portable electronic device; and
at least one mechanical dome associated with the at least one actuator, the at least one mechanical dome configured to implode and/or expand responsive to activation of a button on the display of the portable electronic device to provide a user with tactile feedback associated with the button.

9. The dome assembly of claim 8, wherein the portable electronic device comprises a plurality of buttons and wherein each of the plurality of buttons has a corresponding actuator-dome pair.

10. The dome assembly of claim 8, wherein the portable electronic device comprises a plurality of buttons and wherein the plurality of buttons have a single corresponding actuator-dome pair.

11. The dome assembly of claim 8, further comprising a window associated with the display and wherein the at least one mechanical dome is directly connected to the window and wherein the associated at least one actuator is configured to control a state of the dome.

12. The dome assembly of claim 8, further comprising a window associated with the display, wherein the display has an associated display assembly, wherein the at least one mechanical dome is connected to the display assembly and wherein the associated at least one actuator is configured to control a state of the dome.

13. The dome assembly of claim 8, further comprising a window associated with the display, wherein the window has a front portion and first and second side portions, wherein the at least one mechanical dome is connected to a side portion of the window and wherein the associated at least one actuator is configured to control a state of the dome.

14. The dome assembly of claim 8, wherein the button comprises a mechanical and/or virtual button and wherein the actuator comprises at least one of a memory alloy, electrical activated polymer and piezoelectric ceramic actuator.

15. A method of operating a portable electronic device, the method comprising activating a button on a display of the portable electronic device; and
imploding and/or expanding at least one mechanical dome responsive to the activation of the button on the display to provide a user of the portable electronic device with tactile feedback associated with the button.

16. The method of claim 16, further comprising controlling a state of the at least one mechanical dome using at least one actuator associated with the at least one mechanical dome.

17. The method of claim 15, wherein the portable electronic device comprises a plurality of buttons and wherein each of the plurality of buttons has a corresponding actuator-dome pair.

18. The method of claim 15, wherein the portable electronic device comprises a plurality of buttons and wherein the plurality of buttons have a single corresponding actuator-dome pair.

19. The method of claim 15, wherein the button comprises a mechanical and/or virtual button and wherein the actuator comprises at least one of a memory alloy, electrical activated polymer and piezoelectric ceramic actuator.
